(19) United States
(12) Patent Application Publication
(10) Pub. No.: US 2012/0212883 A1
(43) Pub. Date: Aug. 23, 2012

(54) Electronic controller box

(75) Inventors: Craig Hargreaves, Vancouver, WA (US); Martin Carskadon, Vancouver, WA (US)

(73) Assignee: IP Holdings, LLC, Vancouver, WA (US)

(21) Appl. No.: 12/932,223

(22) Filed: Feb. 22, 2011

(51) Int. Cl. H05K 7/00

(52) U.S. Cl. 361/679.01

(57) ABSTRACT

A electronics enclosure that includes essentially two parts, a backing plate and a cover, the backing plate constructed of one sheet of metal having a top lip, a flat plate, a bottom step, a right side, and a left side whereby the top lip and bottom step define an air gap between the flat plate and a mounting surface; the cover constructed of one sheet of metal having a mounting tab, a top cover portion that has an angle between 10 degrees to 45 degrees from flat as defined by the ground, a flat front portion, a bottom portion, a bottom attachment tab and a plurality of fold over edges; the cover constructed and arranged to fit over the backing plate thereby providing a water shedding enclosure for electronics.

### TECHNICAL FIELD

The present invention generally relates to the electronic controller used in the indoor gardening environment and specifically to the electronic chassis solutions available in that application.

### BACKGROUND OF THE INVENTION

The present invention relates to the environment in which plants are grown indoors and to the controller chassis solutions available in this environment. Humid and wet is always a problem in the indoor growing environment, especially for hydroponic systems that have substantial water reserves that are susceptible to evaporation, making for a warm high humid atmosphere. That warm humid atmosphere with water being occasionally splashed or spilled, creates a hostile environment for digital and analog electronics. As the common users for the subject controller consist primarily of hobby growers, there is a need to make the system resistant to misuse which historically includes using the controller chassis as a shelf for nutrients or beverages.

Today's indoor plant growing control systems are expected to monitor conditions such as temperature, humidity, oxygen, and ph levels, while managing pumps, CO2 generators, fans, HVAC units, artificial lighting, and valves. The challenge is to successfully enclose the controller's electronics in an enclosure that protects the electronics from the hostile environment, while allowing for easy install and economical manufacture.

One approach that the industry has taken in enclosing controller electronics is a plastic or polycarbonate enclosure, with a rubber o-ring as a seal on top of the perimeter of the open side. The box has the electronics mounted within, and then a cover compressively seals against the o-ring on the open side making for a “water proof” seal. In practice however, these “water proof” enclosures get moisture within due to condensation, or an ineffectual seal at the user interface components, power cord entry, or outlets.

Water seeping through a button, display seal, or a power plug is a common problem with controller chassis of this type. If moisture or water seeps into a sealed plastic enclosure, the moisture cannot get out, and the inside of the enclosure becomes more destructive to the electronic components than the outside environment that the enclosure was meant to protect against.

A second shortcoming of a plastic box is the lack of heat conduction. The electronics in a sealed plastic box have no available method of cooling, as all of the heated air is trapped. Further, the plastic box does not conduct heat effectively, it insulates, negating the positive effect of heat sinking the electronics to lower operating temperatures.

A third shortcoming of a sealed plastic box when used in the growing environment for plants is UV and other degrading light radiation. High Intensity Discharge (HID) lamps produce damaging light and heat, that over time and exposure, degrades plastic components.

The hobby grower often is the cause for failure of electronics in the indoor growing environment. Accidentally spilled or sprayed water that gets within an enclosure destroys electronics if the electronics are mounted towards the bottom of the chassis. Water that gets in and can't get out is also a common cause of electronic failure as the heat generated from the electronics causes evaporation that further increases the humidity within the enclosure causing corrosion and failures.

Misuse as a shelf can cause the chassis to fail structurally or be susceptible to leaks, drips, or condensation from items put on the chassis top.

Current electronic controller chassis solutions do not effectively provide passive cooling for the electronics located within the chassis while providing a water shedding enclosure that prevents the trapping of moisture therein while by design, is preventative to misuse as a shelf.

### OBJECTS AND ADVANTAGES

Provide a chassis to protect controller electronics from the hostile indoor growing environment commonly encountered in a green house, a grow tent, or an indoor grow room as operated by the hobby grower. The problem of inexpensively containing sensitive controller electronics in wet or humid environments is solved by successfully enclosing the electronics in a water resistant enclosure constructed from sheet metal comprising a mounting platform that also acts as a heat sink that is enclosed by a cover that is impervious to dripped, splashed, or spilled water, having an top cover portion that promotes the shedding of water while preventing placement of vessels of liquid on the controller chassis. A secondary unanticipated benefit of the top cover portion is the distinguishing display platform for logo or brand name when displayed at retail stores or product conventions.

The chassis has many advantages over the prior art, including:
impervious to splashed or spilled water
integral heat sink for temperature sensitive electronics
top cover portion to shed water
top cover portion to prevent misuse as shelf, things placed on top slide off
cooling air gap between the flat plate and the mounting surface
easy to install electronic components as provided by the two part construction
resistant to ultraviolet radiation
inexpensive sheet metal construction
secondary advantage relates to the top cover portion providing an area for displaying a distinguishing logo or product identifier, such that the consumer's attention is attracted to the enclosure
lightweight, structurally integral enclosure

### SUMMARY OF THE INVENTION

According to one embodiment shown herein as the preferred embodiment, the invention provides an enclosure to protect controller electronics. Throughout this specification reference to features, advantages, or other descriptive or illustrative language does not imply or suggest that all of the features and advantages that may be realized with the present invention should be or are in any way limited by the single embodiment shown herein. Language referring to the features and advantages should be understood to mean that a specific feature, advantage, or characteristic described in connection with an embodiment is included in at least one embodiment of the present invention. Discussion of the features and advantages, and similar language, throughout this specification may, but do not necessarily, refer to the same embodiment, and can be simply illustrative of how other embodiments may be derived from the inventive features and elements described herein. Different sizes and shapes utilized in different embodiments than shown are all part of the inventive art.

The chassis has two components, a backing plate and a cover constructed entirely from sheet metal, and after the electronic components are installed, the two components are attached together with common threaded fasteners, rivets, or other through hole fastener techniques. The electronic components are vertically contact mounted and heat sinked to the flat plate on the opposite side of the air gap, thereby encouraging conductive cooling while keeping the electronics clear of the chassis bottom where water may collect during condensation conditions. A second advantage of mounting the electronics vertically on the flat plate is that any condensation within the enclosure will drip down more towards the flat front portion of the cover, because of the cover's slanted top cover portion. Electrical components relating to user interface such as buttons, plugs, or displays sealingly secure into apertures of the cover.

The electronics, and outlet plugs are installed onto the mounting platform, and user interface buttons, displays, or plugs install into the cover's flat front portion, having the bottom of the cover receive the power cord and sensor wires. The cover is placed over the mounting platform and conductive connections are made between the components mounted on the mounting platform to the components mounted within and through the cover. After all electrical connections are made, the cover and backing plate are mated together by placing the cover over the backing plate and fixated with through hole fasteners such as bolts, rivets, screws, and assembly is complete.

After the cover is attached to the mounting platform, the enclosure is impervious to splashed or spilled water when falling from above, while still allowing a small amount of air communication between the electronics and the outside environment. Louvered vents or other air apertures may be cut into the cover or mounting platform to increase external air communication for additional cooling of electrical components that require greater heat dissipation, and so long as the top cover portion remains continuous and sealed, the most common water hazard from falling from above is protected against.

The air communication between the internal space within enclosure and the outside environment is necessary to allow moist air within to escape the chassis enclosure when the electronics are at heated operating temperatures.

The top cover portion sheds water when spilled or splashed, and prevents the misuse of setting objects, drinks, or nutrients on top of the controller box. The prior art and currently sold electronic controllers sold today, are enclosed in box type enclosures, having a flat top that is parallel to the ground, having no slope or slant. The instant invention benefits from an angled top cover portion, the angle of the top was a balanced development tradeoff between manufacturing costs and the water shedding performance of the enclosure. More material is needed the steeper the angle of the top, and a steeper top complicated the assembly process. While testing different angles for the top, an unexpected secondary benefit was observed. In practice, most controller enclosures are mounted 3-5 feet off the ground when displayed at retail stores or product conventions, thereby making the top cover portion below eye level to the would be consumer. Lights are almost always located directly above and directing light down towards the displays at retail stores, and for product conventions. Product identifiers like logos or art located on this angled top cover portion were better illuminated from above than the same logos or art placed on the flat front portion. As the logo or art on the angled top cover portion was better illuminated by more light, an unexpected result of capturing the eye of the user was observed during development. Through further development efforts, a range of angles for the top cover portion were determined that maintained the easy assembly feature, had good water shedding performance, prevented misuse as a shelf, and attracted consumers' attentions to the product identifiers. The successful angles meeting the above objectives and criteria while maintaining all of the disclosed advantages, was for the top cover portion as compared to ground to be at least 10 degrees, and no more than 45 degrees in slope angle. For the preferred embodiment shown herein, a mid angle within the range was shown at 23 degrees.

The accompanying drawings, which are incorporated in and constitute part of this specification, and are included to illustrate and provide a further understanding of the sheet metal construction, configuration of components, and visually explain the features and function of the invention.

The electronic components and conductive connections are not shown in the below figures or described herein, as it is well known in the art how to install electrical components on to a flat plate. It is also well known and understood in the art how to attach electrical components through sheet metal apertures.

### BRIEF DESCRIPTION OF DRAWINGS

FIG. 1 is a right perspective view of a back plate of an electronic controller box;

FIG. 2 is a right perspective view of a cover of an electronic controller box;

FIG. 3 is a left side view of a cover shown in FIG. 2;

FIG. 4 is a left side view of a back plate shown in FIG. 1;

FIG. 5 is an exploded perspective view of a cover and back plate of the preferred embodiment;

FIG. 6 is a front view of a back plate cut out of a flat piece of metal as shown in FIG. 1;

FIG. 7 is a front view of a cover cut out of a flat piece of metal as shown in FIG. 2;

FIG. 8 is a perspective view of the preferred embodiment completely assembled and;

FIG. 9 is a left side view of a cover as shown in FIG. 3 in relationship to an observer viewing the embodiments.

REFERENCE NUMERALS

| | |
|---|---|
| 10 | Backing Plate |
| 11 | First Step Bend |
| 12 | Second Bend Plate |
| 13 | Third Top Bend |
| 14 | Fourth Left Bend |
| 15 | Fifth Right Bend |
| 20 | Top Lip |
| 21 | Top Lip Holes |
| 30 | Right Side |
| 31 | Right Side Holes |
| 32 | Screws |
| 35 | Outlet Holes |
| 36 | Outlet |
| 40 | Left Side |
| 41 | Left Side Holes |
| 50 | Bottom Step |
| 51 | Bottom Step Holes |
| 52 | Vertical Plate Mount |
| 55 | Mount Hole |
| 60 | Gap Height |
| 65 | Gap Width |
| 70 | Air Gap |
| 80 | Flat Plate |
| 85 | Mounting Holes |
| 90 | Mounting Surface |
| 100 | Cover |
| 110 | Mounting Tabs |
| 115 | Top Tab Holes |
| 120 | Top Cover Portion |
| 124 | Flat |
| 125 | Slope Angle |
| 129 | Control Holes |
| 130 | Flat Front Potion |
| 132 | Indicatior Holes |
| 133 | Installed LEDs |
| 135 | Switch Hole |
| 136 | Switch |
| 140 | Bottom Portion |
| 149 | Electrical Power Cord |
| 150 | Bottom Attaching Tab |
| 151 | Bottom Tab Holes |
| 155 | Power Inlet |
| 156 | Sensor Inlet |
| 157 | Sensor Cord |
| 160 | Fold Over Edges |
| 161 | Right Edge Holes |
| 162 | Left Edge Holes |
| 201 | First Bottom Tab Bend |
| 202 | Second Bottom Bend |
| 203 | Third Front Bend |
| 204 | Forth Top Bend |
| 205 | Left Fold Bend |
| 206 | Right Fold Bend |

### DETAIL DESCRIPTION OF DRAWINGS

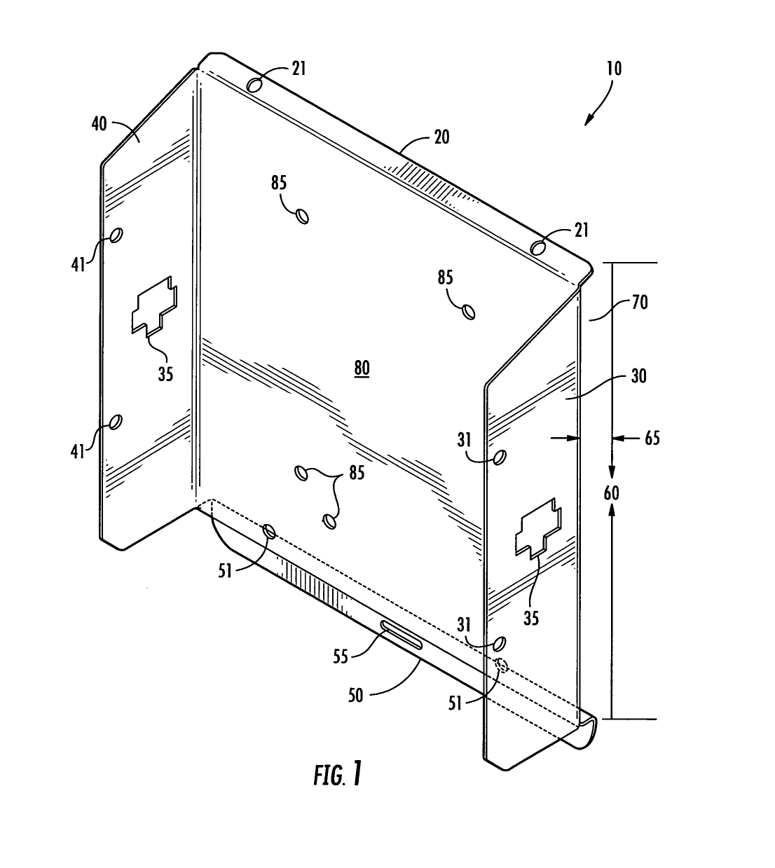

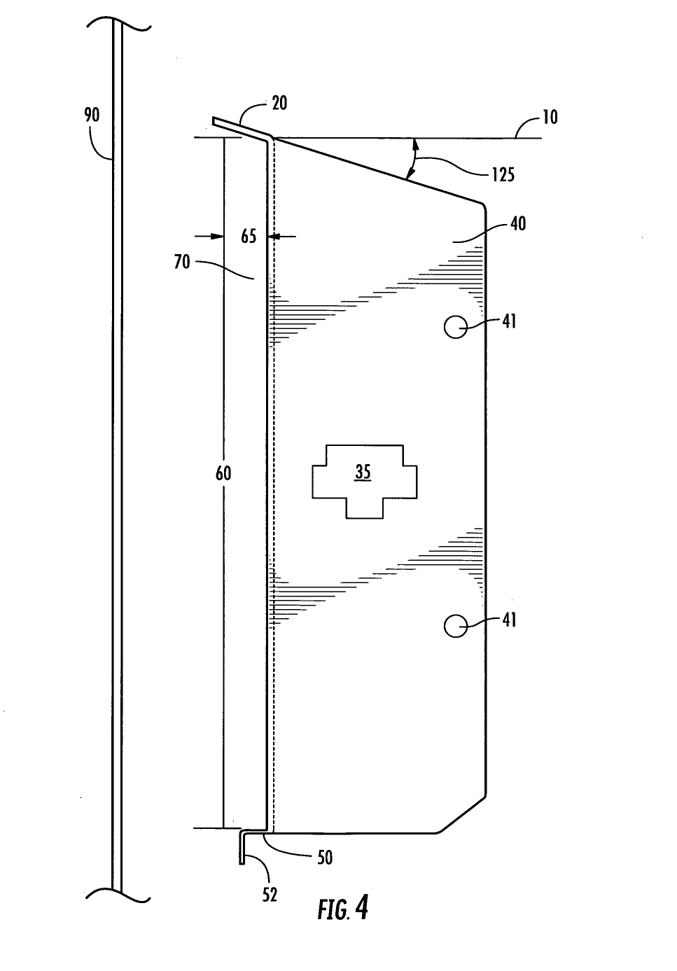

FIG. 1 is a perspective view that illustrates the backing plate 10 having a top lip 20, a right side 30, a left side 40, and a bottom step 50 with step mount hole 55 as a mounting means to the mounting surface shown in later figures. The top lip 20 and bottom step 50 thereby defining the air gap 70 in gap height 60 and gap width 65, as between the flat plate 80 and the mounting surface as shown in FIG. 4. The flat plate 80 having the air gap 70 on one side and on the other side a plurality of mounting holes 85 are positioned and arranged to heat sink and secure electronic components or circuit boards to the interior of the flat plate 80, thereby facilitating passive cooling through thermal conduction into the sheet metal of the flat plate 80 at the location opposite of the air gap 70, the air gap 70 allowing air communication across the opposing sheet metal side that the electronics are mounted on.

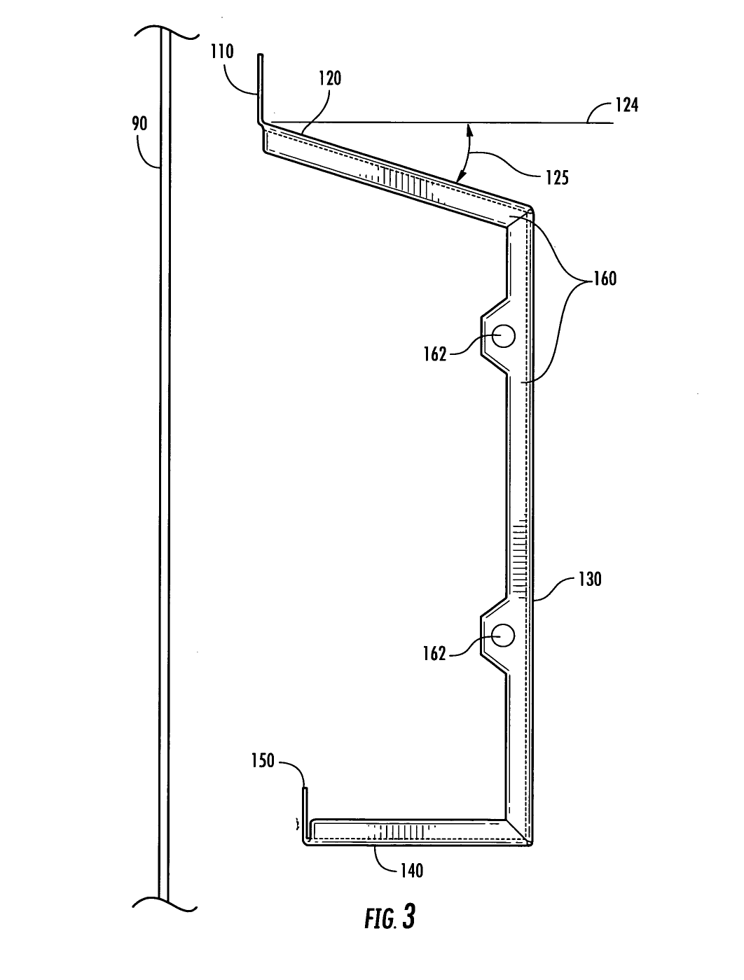

Not all applications allow for a smooth flat mounting surface 90 as shown in FIG. 3, and the secondary unanticipated benefit of having an air gap 70 of at least 0.1 inches in gap width 65 was the versatility of mounting the backing plate 10 to more available surfaces like those available in a grow room; barrels, buckets, round posts, and the like having raised lettering or ridges. Outlet holes 35 are cut out on the right side 30 and left sides 40 in size and number matching the requirements of the specific application.

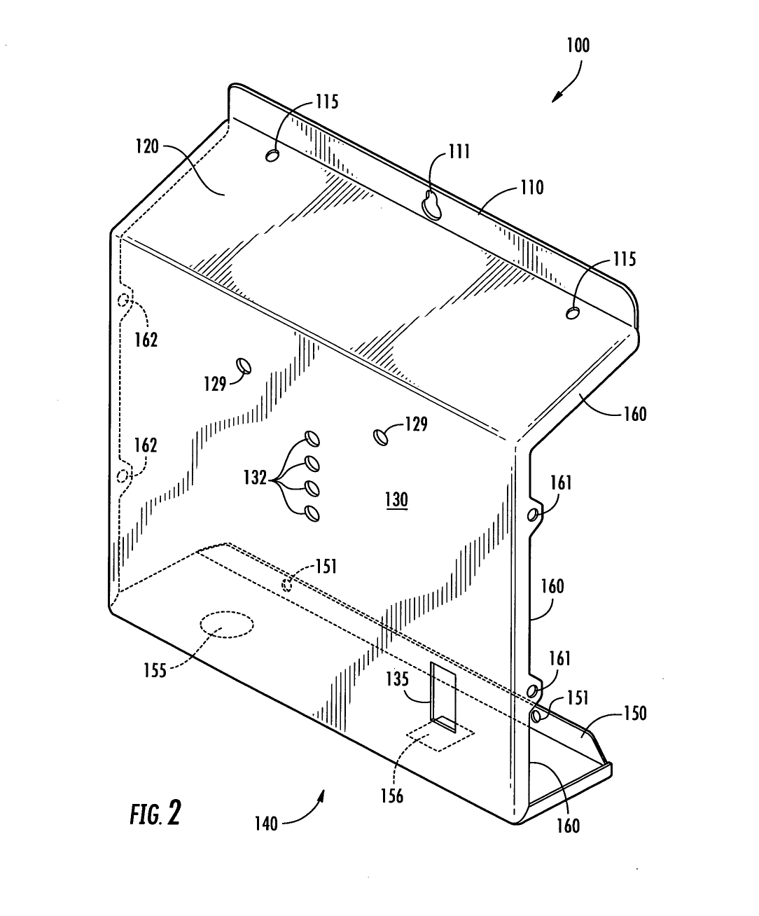

FIG. 2 is a perspective view that illustrates the cover 100 having a top mounting tab 110, a top cover portion 120, a flat front portion 130, a bottom portion 140, a bottom attaching tab 150, and a plurality of fold over edges 160, such that when the cover 100 is attaching to the backing plate 10, the fold over edges 160 over lap the right side 30 exposed edges and left side 40 exposed edges of the backing plate 10 shown in FIG. 1, thereby protecting the electronic components within from water spray and drips from above. Electrical power is brought in through the power inlet 155 and the sensor connection is brought in through the sensor inlet 156. Control holes 129 may be of any size and shape, depending on the type of user controls to be installed. Indicator holes 132 may also be of any size or shape as required for visual display.

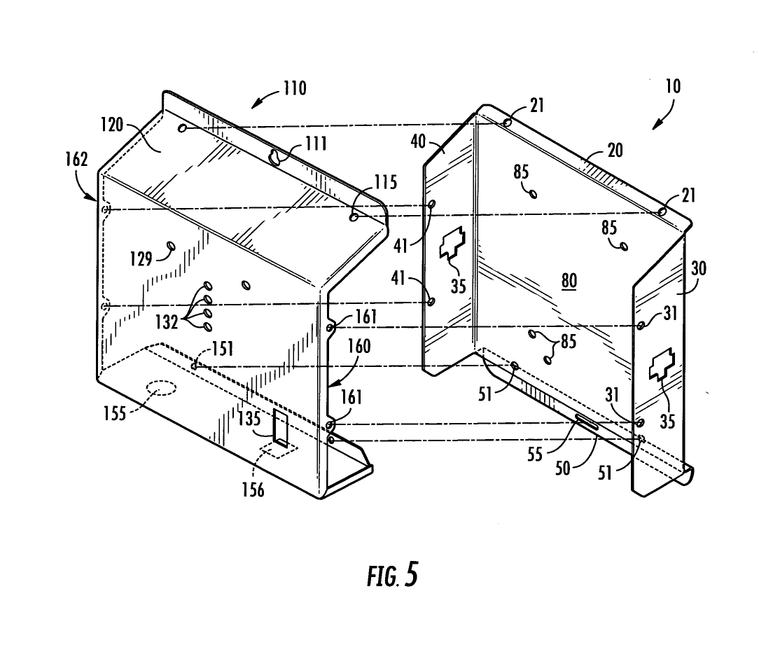

FIG. 3 is a left side view of the cover 100. The top cover portion 120 is sloped down away from the top mounting tab 110. The mounting tab 110 is parallel to the mounting surface 90. The slope angle 125, for the top cover portion 120, which in the preferred embodiment is approximately 67 degrees up from the mounting tab 110 that then results in a 23 degree angle down from flat 124, or in other words 23 degrees down from being perpendicular to the mounting surface 90. When assembled and installed as shown in the following figures, the slope angle 125 encouraging water to run off the top cover portion 120 without pooling which by experience eventually develops into leaks at the top tab holes 115 shown in FIG. 5. The slope angle 125 further discourages misuse of the top cover portion 120 as a shelf, which eventually leads to spills or other misuse type failures.

FIG. 4 is a left side view of the backing plate 10 showing a top lip 20, a left side 40, and a bottom step 50 having the vertical plate mount 52 parallel with the mounting surface 90. The top lip 20 and bottom step 50 thereby defining the air gap 70 in gap height 60 and gap width 65, as between the backing plate 10 and the mounting surface 90. Outlet holes 35 are cut out of the left sides 40 in size and number matching the requirements of the specific application. If two items are to be controlled from the left side 40, then two outlet holes 35 would be cut out. Two left side holes 41 facilitate the fixation to the cover 100 as shown in FIG. 5 and may be threaded or have nuts fixated on the interior side. The angle of the top of the left side 40 and right side 30 share the same slope angle 125 as the cover, thereby providing a fitting and sealed fixation of the cover 100 lapping over at the cover's 100 fold over edges 160 and the backing plate 10 at it's exposed edges of the right side 30 and left side 40.

FIG. 5 is a perspective exploded view of the disassembled preferred embodiment of the chassis showing the cover 100 aligned with the backing plate 10.

The fold over edges 160 of the cover 100 go over the right side 30 and left side 40. The right side holes 31 and left side holes 41 align with corresponding right edge holes 161 and left edge holes 162, the top lip holes 21 align with the top tab holes 115, and the bottom tab holes 151 align with the bottom step holes 51. In the preferred embodiment, the backing plate 10 holes are threaded or benefit from threaded nuts permanently attached to the inside of the right side holes 31, left side holes 41, top lip holes 21, and bottom step holes 51 constructed to receive a screw or bolt fastener that fit through the cover 10 holes for easier assembly.

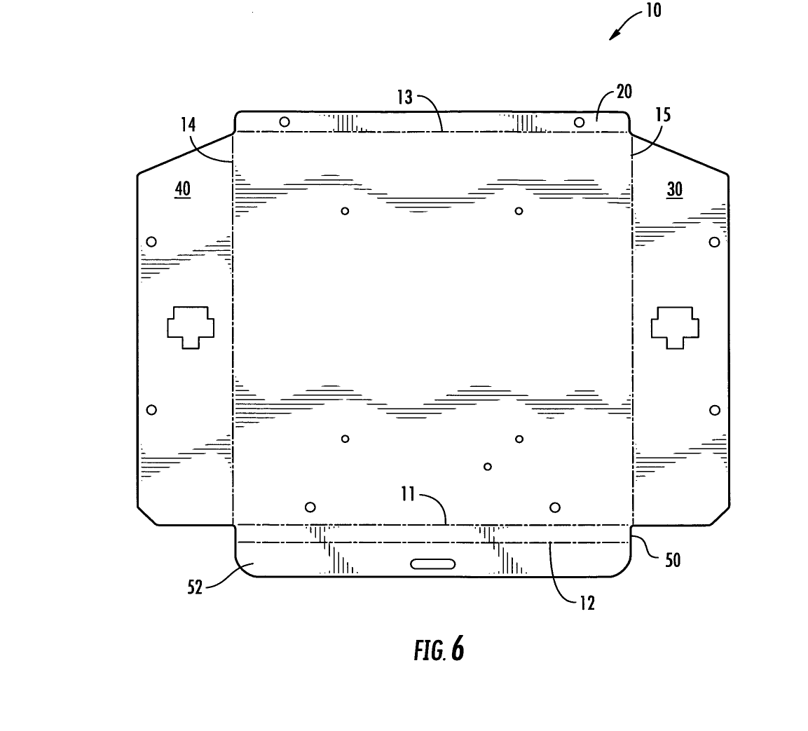

FIG. 6 is a flat sheet metal cut out of the backing plate 10 of the preferred embodiment before bending into shape. Each bend is shown as a hidden line. In the preferred embodiment, the first step bend 11 defines the bottom step 50 which is bent 90 degrees up. Forming the vertical plate mount 52, the second plate bend 12 is bent 90 degrees up. The third top bend 13 defines the top lip 20 and is bent 67 degrees up, and must be matching the slope angle 125 shown in FIG. 3. The fourth left bend 14 defines the left side 40 and is bent 90 degrees down. The fifth right bend 15 defines the right side 30 and is bent 90 degrees down. After the sheet metal cut out is completed and the bends made, the backing plate 10 is completely formed.

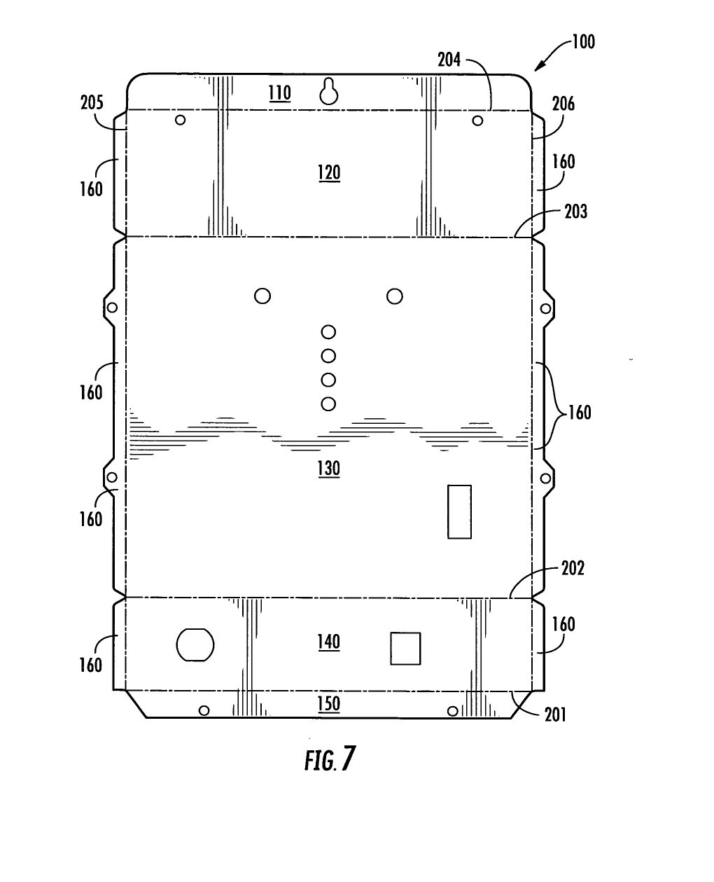

FIG. 7 is a flat sheet metal cut out of the cover 100 before bending into shape. In the preferred embodiment, the first bottom tab bend 201 defines the bottom attaching tab 150, and is bent 90 degrees down. The second bottom bend 202 defines bottom portion 140 and is bent 90 degrees down. The third front bend 203 defines the flat front portion 130, and is bent 67 degrees down. The fourth top bend 204 defines the top cover portion 120, and is bent 67 degrees up. The fold over edges 160 on the left side are defined by bending down 90 degrees along the left fold bend 205. The fold over edges 160 on the right side are defined by bending down 90 degrees along the right fold bend 206.

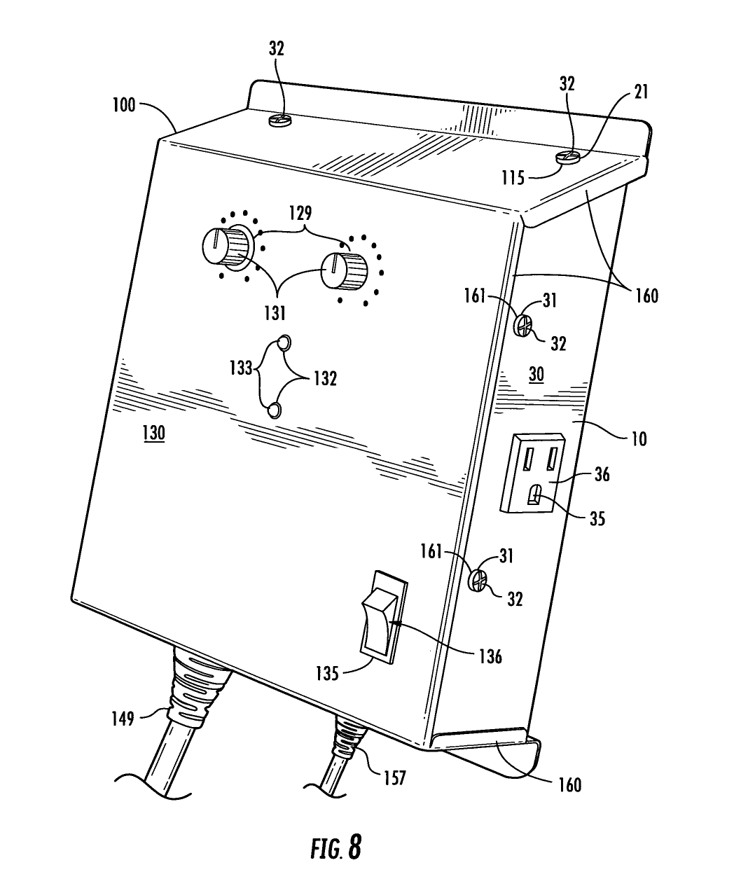

FIG. 8 is a perspective view of the preferred embodiment completely assembled having electronic components installed for illustration and further understanding. The fold over edges 160 of the cover 100 shown covering over the right side 30. The right side holes 31 of the backing plate 10 shown in FIG. 5 align with corresponding right edge holes 161 of the cover 100 and are fastened together via screws 32. The top lip holes 21 of the backing plate 10 align with the top tab holes 115 of the cover 100 and are fastened together via screws 32. The bottom tab holes 151 align with the bottom step holes 51 and are fastened via screws, as shown in FIG. 5. Electrical power cord 149 is brought in through the power inlet 155 shown in FIG. 2. The sensor cord 157 is brought in through the sensor inlet 156 shown in FIG. 2. Outlet holes 35 is filled with outlet 36 allowing for controlled electrical connection to a light fixture, pump, fan, or any other electrically powered component used in the plant growing environment. Control holes 129 for this embodiment are filled with installed turn pots 131, but any user control knob, button, switch or component may be used depending on application. Indicator holes 132 are filled with installed LEDs 133, but may also be filled with LCD screens, mechanical color indicators, or various other light backed components.

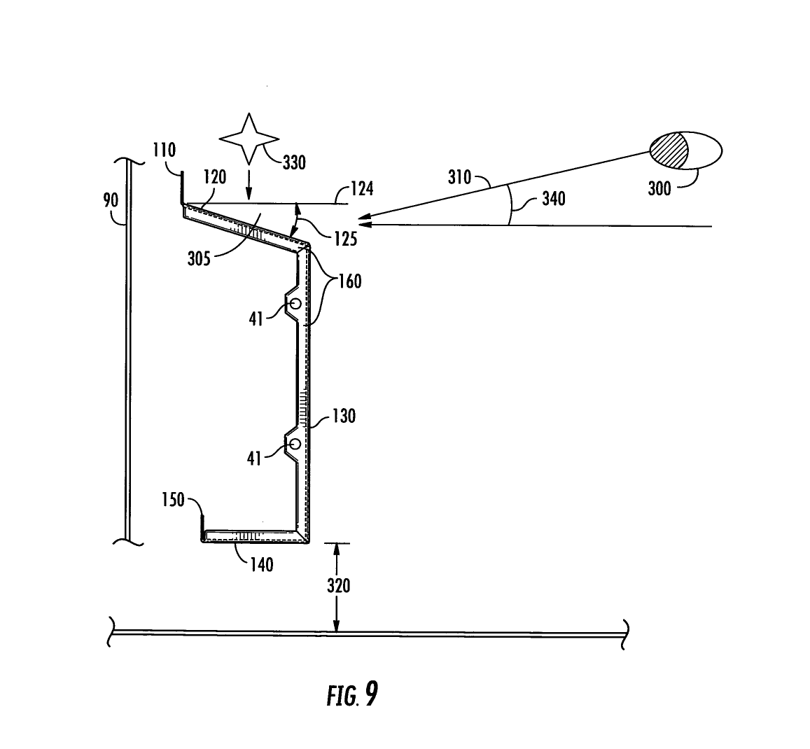

FIG. 9 is a side view of the cover 100 as shown in FIG. 3. The slope angle 125 of the top cover portion of the enclosure is a result effective variable which can be optimized depending on application as discussed below. The eye 300 of the observer is shown above the cover 100 mounting height 320. The product identifying logo 305 is located on the top cover portion 120 that has a slope angle of 125 as compared to the ground. Light 330 from above provides enhanced illumination increasing the visibility of the logo 305. As the mounting height 320 is decreased, the observer eye 300 has a greater perspective angle 340 and the necessary slope angle 125 to still have the benefit of the visual affect decreases. As the mounting height 320 increases, the perspective angle 340 decreases, and the necessary slope to angle 125 to still have the benefit of the visual affect increases. At least 10 degrees is needed to shed water and provide the advantage of enhancement of visual distinction and no more than 45 degrees of slope angle 125 for higher mounting locations, as any more slope angle 125 over 45 degrees complicates manufacturing and assembly.

We claim:

1. A electronics enclosure comprising:
a backing plate constructed of one sheet of metal having a top lip, a flat plate, a bottom step, a right side, and a left side;
a cover constructed of one sheet of metal having a mounting tab, a top cover portion, a flat front portion, a bottom portion, a bottom attachment tab and a plurality of fold over edges;
the top cover portion having a slope angle of no less than 10 degrees and no more than 45 degrees; and
the cover constructed and arranged to fit over the backing plate thereby providing a water shedding enclosure for electronics.

2. A electronics enclosure comprising:
a backing plate constructed of one sheet of metal having a top lip, a flat plate, a bottom step, a right side, and a left side whereby the top lip and bottom step define an air gap between the flat plate and a mounting surface;
a cover constructed of one sheet of metal having a mounting tab, a top cover portion, a flat front portion, a bottom portion, a bottom attachment tab and a plurality of fold over edges; and
the cover constructed and arranged to fit over the backing plate thereby providing a water shedding enclosure for electronics.

3. A electronics enclosure comprising:
a mounting platform constructed of one sheet of metal having;
a flat plate defining the shape and size of the enclosure;
a top lip extending from the top bend of the flat plate toward the mounting surface at an angle no less than 45 degrees and no more than 80 degrees;
a bottom mounting tab extending from the bottom bend of the flat plate towards the mounting surface;
a right side having a top edge on plane with the top lip extending from the right bend of the flat plate away from the mounting surface;
a left side having a top edge on plane with the top lip extending from the left bend of the flat plate away from the mounting surface;
a cover constructed of one sheet of metal having;
a flat front portion
a top cover portion extending from the top bend of the flat front portion towards the mounting surface at an angle matching the top lip;
a top mounting tab extending from the top cover portion and parallel to the surface of the flat front portion;
a bottom portion extending from the bottom bend of the flat front portion towards the mounting surface;
a bottom attaching tab extending from the bottom portion and parallel to the surface of the flat front portion;
a right fold over edge extending perpendicular from the right bend of the top cover portion towards the mounting surface;
a left fold over edge extending perpendicular from the left side bend of the top cover portion towards the mounting surface;
a right fold over edge extending perpendicular from the right bend of the face plate towards the mounting surface;
a left fold over edge extending perpendicular from the left side bend of the face plate towards the mounting surface;
the cover constructed and arranged to fittingly secures over the mounting platform.

4. A electronics enclosure as set forth in claim 2, wherein the top cover portion has a slope angle of at least 10 degrees, but no more than 45 degrees.

5. A electronics enclosure as set forth in claim 2, wherein the gap width is at least 0.1 inches.

6. A electronics enclosure as set forth in claims 1, 2 and 3, wherein the flat front portion has at least one aperture constructed to receive electronic component.

7. A electronics enclosure as set forth in claims 1, 2 and 3, wherein right side and left side of the backing plate have at least one aperture constructed to receive electronic component.

8. A electronics enclosure as set forth in claims 1, 2 and 3, wherein the flat plate is constructed to receive electronic components or electronic circuit boards.

9. A electronics enclosure as set forth in claims 1, 2 and 3, wherein right side and left side of the backing plate have at least one aperture constructed to receive electronic component.

10. A electronics enclosure as set forth in claims 1, 2 and 3, wherein the flat plate is constructed to receive electronic components or electronic circuit boards.

11. A electronics enclosure as set forth in claim 1, 2 and 3, wherein the bottom portion has at least one aperture to receive power cords or wires.

12. A electronics enclosure as set forth in claims 1, 2 and 3, wherein the bottom mounting tab includes a bottom step, the bottom step and top lip defining an air gap as between the flat plate and the mounting surface.
